(19) United States
(12) Patent Application Publication
(10) Pub. No.: US 2014/0231838 A1
(43) Pub. Date: Aug. 21, 2014

(54) SEMICONDUCTOR LIGHT-EMISSION DEVICE AND MANUFACTURING METHOD

(71) Applicant: Sony Corporation, Tokyo (JP)

(72) Inventors: Kota Tokuda, Kanagawa (JP); Makoto Oota, Miyagi (JP); Takayuki Kawasumi, Kanagawa (JP)

(73) Assignee: Sony Corporation, Tokyo (JP)

(21) Appl. No.: 14/167,655

(22) Filed: Jan. 29, 2014

(30) Foreign Application Priority Data
Feb. 19, 2013 (JP) 2013-030400

(51) Int. Cl. H01L 33/30

(52) U.S. Cl. CPC H01L 33/30
USPC 257/94; 438/47

(57) ABSTRACT

A semiconductor light-emission device includes: a p-type conductive layer that is one or more layers each made of a III-V compound semiconductor; an active layer made of a III-V compound semiconductor; and an electron barrier layer inserted between the p-type conductive layer and the active layer, and made of a III-V compound semiconductor. The electron barrier layer includes first and second regions. The first region is provided closer to the active layer than the second region, has a first interface and a second interface located farther from the active layer than the first interface, and has a band gap of a fixed magnitude. The second region is provided in contact with the second interface, and has a band gap smaller than the band gap of the first region and becomes smaller from an interface with the first region towards an interface with the p-type conductive layer of the second region.

### CROSS REFERENCE TO RELATED APPLICATIONS

This application claims the benefit of Japanese Priority Patent Application JP2013-30400 filed Feb. 19, 2013, the entire contents of which are incorporated herein by reference.

### BACKGROUND

The present technology relates to a semiconductor light-emission device and a manufacturing method, and, in particular, to a semiconductor light-emission device and a manufacturing method which are capable of causing a semiconductor laser to emit light more efficiently.

In recent years, a semiconductor light-emission device using a compound semiconductor has been widely used as an optical-disk light source or an illumination light source. Meanwhile, development of higher output and more reliable semiconductor light-emission devices has been pursued to increase capacity of optical disks, and to improve writing speeds and illumination luminance.

A high-output semiconductor light-emission device is expected to achieve high output with low driving power. For example, when a large current is injected to obtain high luminance and high output, light efficiency of the semiconductor light-emission device may decrease, and the driving power may increase.

As one of factors behind the decrease in the light efficiency of the semiconductor light-emission device, an increase in loss due to an electron overflow is well known. In the electron overflow, electron carriers leak on a p-type cladding layer side after crossing a barrier layer, without recombining in an active layer, as the injected current increases. A semiconductor light-emission device with a large amount of electron overflow causes an increase in threshold current and a decrease in differential efficiency, which makes it difficult to achieve low driving power.

The electron overflow occurs more clearly, in a high temperature operating environment in particular. In the high-output semiconductor light-emission device, a driving temperature of the device becomes higher, and therefore the loss due to the electron overflow becomes clearer, as compared with a case of a low-output semiconductor light-emission device. In addition, the increase of the loss also increases a heating value of the device at the time of driving, thereby easily causing deterioration attributable to major damage by heat to an active layer, an end face, and a package. This is disadvantageous in terms of reliability.

Therefore, for example, there has been proposed a structure in which an electron barrier layer having a band gap larger than that of a p-type cladding layer is provided between an active layer and the p-type cladding layer (see, for example, Japanese Unexamined Patent Application Publication No. H10-126006).

This makes, as compared with an amount of conduction-band band discontinuity (an electron barrier height) formed at an interface between the p-type cladding layer and a barrier layer provided around the active layer, an amount of conduction-band band discontinuity formed at an interface between the electron barrier layer and the barrier layer become larger. Therefore, electron carriers are prevented from easily reaching the p-type cladding layer by crossing the barrier layer. As a result, the electron overflow is suppressed.

Further, for example, a material with a large band gap may be configured by increasing an Al elemental composition ratio in a III-V compound semiconductor. Depending on the structure of the semiconductor light-emission device, a light-guide layer may be provided between the p-type cladding layer and the electron barrier layer, and an effect of suppressing the electron overflow by virtue of the electron barrier layer may be expected in this case as well.

Furthermore, as a structure by which an effect of further suppressing the electron overflow may be expected, it has been proposed, for example, to make a band gap of a last barrier layer, which is adjacent to an active-layer-side interface of an electron barrier layer, become smaller than those of other barrier layers (for example, see Japanese Unexamined Patent Application Publication No. 2006-165519).

This reduction of the band gap of the last barrier layer further increases an amount of conduction-band band discontinuity formed at an interface of the last barrier layer adjacent to the active-layer-side interface of the electron barrier layer. Therefore, electron carriers are prevented from easily reaching a p-type cladding layer. As a result, the electron overflow is suppressed.

Still furthermore, there has been proposed such a technique that an Al elementary composition of an electron barrier layer has a structure of providing modulation to increase a band gap from a p-type cladding layer side towards an n-type cladding layer side. This is to alleviate a decline in efficiency of supplying positive holes to an active layer due to an electron barrier layer, and to thereby avoid deterioration in characteristics of a semiconductor laser device (for example, see Japanese Unexamined Patent Application Publication No. 2011-187591).

This eases a valence band barrier to hole carriers at an interface between the p-type cladding layer and the electron barrier layer, which makes it possible to alleviate a decline in efficiency of injecting positive holes to the active layer due to the electron barrier layer. As a result, it is possible to obtain a semiconductor laser device with a low threshold current value.

### SUMMARY

However, for example, when the structure including the electron barrier layer disclosed in JP H10-126006A is used, a band discontinuity may be caused not only in the conduction band but also in a valence band. In particular, in a band discontinuity part of the valence band at the interface between the p-type cladding layer and the electron barrier layer, highly-concentrated hole carriers are localized, which generates a large lateral hole current at the interface between the p-type cladding layer and the electron barrier layer.

For example, in a case of a semiconductor laser, hole carriers spreading to outside of a gain region and becoming a loss without contributing to laser oscillation may be increased by the lateral hole current. This causes a threshold current value to rise, and characteristics of the semiconductor laser device to deteriorate.

Further, for example, when the structure including the electron barrier layer disclosed in JP 2006-165519A is used, a large lateral hole current may be generated at the interface between the p-type cladding layer and the electron barrier layer, and moreover, hole carriers may be accumulated in the barrier layer formed between the active layer and the electron barrier layer. For this reason, the lateral hole current is more easily generated, and the loss also becomes greater.

Furthermore, when the structure disclosed in JP 2011-187591A is used, the effect of suppressing the electron overflow becomes insufficient, which leads to a new disadvantage that is deterioration of characteristics such as differential efficiency.

For example, in the technique of JP 2011-187591A, the degree of the effect of suppressing the electron overflow may be determined mainly by the magnitude (electron barrier height) of the amount of conduction-band band discontinuity formed at the interface between the electron barrier layer and the barrier layer.

For example, in a semiconductor light-emission device using a nitride compound semiconductor, an internal electric field caused by spontaneous polarization or piezopolarization may exist, and therefore, a conduction band of an electron barrier layer may have a shape becoming higher from an active layer side towards a p-type cladding layer side. In this case, an effective electron barrier height that determines the effect of suppressing the amount of electron overflow is a difference between a conduction band energy position of a barrier layer and the highest conduction-band energy peak position in the electron barrier layer. Therefore, a band shape in the electron barrier layer also affects the effect of suppressing the electron overflow.

However, adopting the structure disclosed in JP 2011-187591A, rather, lowers the conduction-band energy peak position in the electron barrier layer. Therefore, the electron barrier height is reduced, and the effect of suppressing the electron overflow declines. As a result, characteristics of the light-emission device deteriorate.

It is desirable to allow a semiconductor laser to emit light more efficiently. According to an embodiment of the present technology, there is provided a semiconductor light-emission device including: a p-type conductive layer that is one or more layers each made of a III-V compound semiconductor; an active layer made of a III-V compound semiconductor; and an electron barrier layer inserted between the p-type conductive layer and the active layer, and made of a III-V compound semiconductor, the electron barrier layer including a first region and a second region. The first region is provided closer to the active layer than the second region in the electron barrier layer, has a first interface and a second interface that is located farther from the active layer than the first interface, and has a band gap of a fixed magnitude. The second region is provided in contact with the second interface of the first region, and has a band gap of a magnitude that is smaller than the magnitude of the band gap of the first region and becomes smaller from an interface with the first region of the second region towards an interface with the p-type conductive layer of the second region.

The semiconductor light-emission device may further include a band discontinuity point at which the magnitudes of the band gaps at the interface between the first region and the second region become discontinuous.

The second region may be divided into a plurality of regions that have different band gaps from one another, and the plurality of regions may be disposed to have the band gaps smaller from the interface with the first region towards the interface with the p-type conductive layer.

In the second region, the magnitude of the band gap at the interface with the first region may be equal to the magnitude of the band gap of the first region, and the magnitude of the band gap may change continuously from the interface between the first region and the second region to the interface with the p-type conductive layer.

The III-V compound semiconductor forming the electron barrier layer may be a III-V compound semiconductor including nitrogen.

The III-V compound semiconductor forming the electron barrier layer may be a III-V compound semiconductor including nitrogen, aluminum, and gallium, and an elemental composition ratio of the aluminum of the first region may be about 5% to about 20%.

The first region of the electron barrier layer may have a film thickness that is about 50 angstroms to about 500 angstroms.

According to an embodiment of the present technology, there is provided a method of manufacturing a semiconductor light-emission device, the method including: providing, in an electron barrier layer of the semiconductor light-emission device, a first region having a band gap of a fixed magnitude, the electron barrier layer being made of a III-V compound semiconductor and being inserted between a p-type conductive layer and an active layer of the semiconductor light-emission device, the p-type conductive layer being one or more layers each made of a III-V compound semiconductor, and the active layer being made of a III-V compound semiconductor; and providing, in the electron barrier layer, a second region that is provided in contact with a second interface of the first region, the first region being provided closer to the active layer than the second region in the electron barrier layer and having a first interface and the second interface that is located farther from the active layer than the first interface, and the second region having a band gap of a magnitude that is smaller than the magnitude of the band gap of the first region and becomes smaller from an interface with the first region of the second region towards an interface with the p-type conductive layer of the second region.

In the above-described embodiments of the present technology, the p-type conductive layer, the active layer, and the electron barrier layer are provided. The p-type conductive layer is one or more layers each made of a III-V compound semiconductor. The active layer is made of a III-V compound semiconductor. The electron barrier layer is inserted between the p-type conductive layer and the active layer, and is made of a III-V compound semiconductor. The electron barrier layer includes the first region and the second region, in which the first region is provided closer to the active layer than the second region in the electron barrier layer, has the first interface and the second interface that is located farther from the active layer than the first interface, and has the band gap of a fixed magnitude. The second region is provided in contact with the second interface of the first region, and has the band gap of a magnitude that is smaller than the magnitude of the band gap of the first region and becomes smaller from the interface with the first region of the second region towards the interface with the p-type conductive layer of the second region.

According to the above-described embodiments of the present technology, a semiconductor laser is allowed to emit light more efficiently.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the present disclosure, and are incorporated in and configure a part of this specification. The drawings illustrate embodiments and, together with the specification, serve to describe the principles of the technology.

FIG. 1 is a cross-sectional diagram of a semiconductor laser according to an embodiment of the present technology.

FIG. 2 is a schematic diagram illustrating a band gap of each of an n-type light-guide layer to a p-type cladding layer of FIG. 1.

FIG. 3 is a diagram used to describe the band gap of each of the n-type light-guide layer to the p-type cladding layer of FIG. 1 in more detail.

FIG. 4 is a diagram illustrating an example of a band gap when a p-type electron barrier layer 16 does not have a band discontinuity point.

FIG. 5 is a diagram illustrating an example of a band gap when an amount of conduction-band band discontinuity at an interface between the p-type electron barrier layer and a barrier layer is made large.

FIG. 6 is a diagram used to describe simulation results according to semiconductor lasers.

FIG. 7 is a schematic diagram illustrating another example of a band gap of each of the n-type light-guide layer to the p-type cladding layer of FIG. 1.

FIG. 8 is a schematic diagram illustrating the example of the band gap of the p-type electron barrier layer in FIG. 7 in detail.

FIG. 9 is a schematic diagram illustrating still another example of a band gap of each of the n-type light-guide layer to the p-type cladding layer of FIG. 1.

FIG. 10 is a diagram used to describe the band gap of FIG. 9 in more detail.

FIG. 11 is a diagram illustrating an example of a band gap when a flat portion of an energy position is not provided.

FIG. 12 is a schematic diagram illustrating still another example of a band gap of each of the n-type light-guide layer to the p-type cladding layer of FIG. 1.

FIG. 13 is a diagram used to describe simulation results according to semiconductor lasers.

FIG. 14 is another diagram used to describe the simulation results according to the semiconductor lasers.

### DETAILED DESCRIPTION

Some embodiments of the technology disclosed herein will be described below with reference to the drawings.

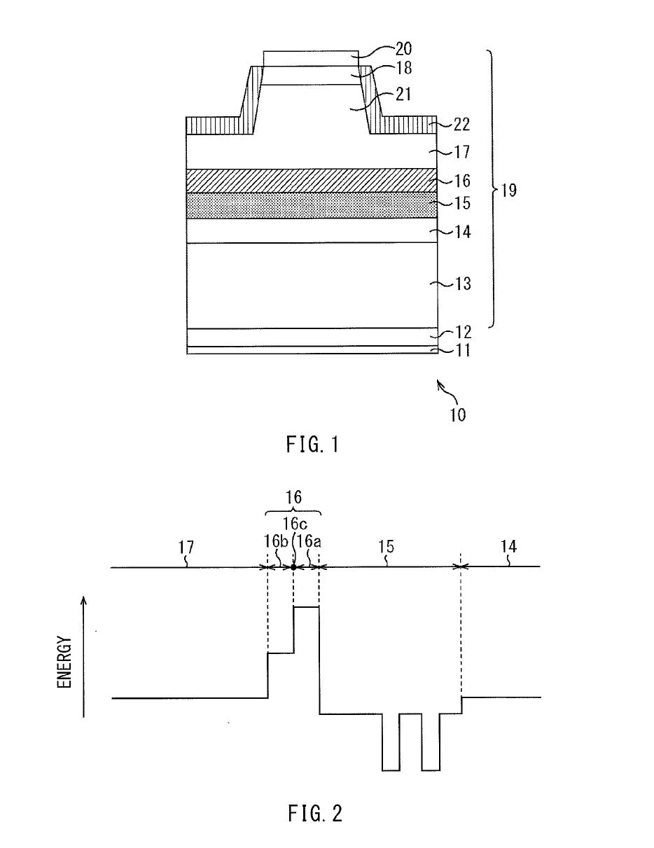

FIG. 1 is a cross-sectional diagram of a semiconductor laser according to an embodiment of the present technology. A semiconductor laser 10 illustrated in this cross-sectional diagram may be configured as, for example, a nitride-based semiconductor laser.

On a lower part and an upper part of FIG. 1, an n-side electrode 11 and a p-side electrode 20 are provided, respectively.

Provided on the n-side electrode 11 is a substrate 12, and a semiconductor layer 19 is formed on the substrate 12. The substrate 12 may be configured as, for example, a c-face GaN substrate. The semiconductor layer 19 is formed of a so-called III-V compound semiconductor.

Provided at a lowermost part of the semiconductor layer 19 in FIG. 1 is an n-type cladding layer 13. For example, the n-type cladding layer 13 may be configured using aluminum gallium nitride (AlGaN), and may be made of an n-type Al_{0.06}Ga_{0.94}N. The n-type cladding layer 13 may have, for example, a thickness of 2 μm, and may be doped with, for example, silicon (Si) or oxygen (O) serving as an n-type impurity.

Formed on the n-type cladding layer 13 is an n-type light-guide layer 14. The n-type light-guide layer 14 may be configured using, for example, gallium nitride (GaN). The n-type light-guide layer 14 may have, for example, a thickness of 100 nm, and may be doped with, for example, silicon (Si) or oxygen (O) serving as an n-type impurity.

Formed on the n-type light-guide layer 14 is an active layer 15. The active layer 15 includes a quantum well layer made of an n-type GaInN layer and a barrier layer made of an n-type GaInN layer. For example, the quantum well layer of the active layer 15 may be made of Ga_{0.92}In_{0.08}N, and have a thickness of 5 nm. In this case, an emission wavelength of the nitride-based semiconductor laser is about 400 nm. The barrier layer of the active layer 15 may be made of Ga_{0.96}In_{0.04}N, and have a thickness of 10 nm, for example. The number of quantum well layers included in the active layer may be, for example, three, and a multiquantum well structure is adopted.

Formed on the active layer 15 is a p-type electron barrier layer 16. The p-type electron barrier layer 16 may be configured using, for example, aluminum gallium nitride (AlGaN). Alternatively, the p-type electron barrier layer 16 may be configured using aluminum gallium indium nitride (AlGaInN).

The p-type electron barrier layer 16 is configured using a material capable of achieving a band gap larger than a band gap of a layer adjacent to an active-layer-side interface, and may include, for example, a first region and a second region. The first region may have a thickness of, for example, 10 nm, and may be doped with, for example, magnesium (Mg) serving as a p-type impurity. The second region may have a thickness of, for example, 20 nm, and may be doped with, for example, magnesium (Mg) serving as a p-type impurity. Detailed configuration of the p-type electron barrier layer 16 will be described later.

Formed on the p-type electron barrier layer 16 is a p-type cladding layer 17. The p-type cladding layer 17 may be configured using, for example, aluminum gallium nitride (AlGaN). For example, the p-type cladding layer 17 may have a super lattice structure in which p-type AlGaN layers each having a thickness of 2.5 nm and having different band gaps are laminated alternately, and an average Al elemental composition ratio may be 1%. In addition, the p-type cladding layer 17 may be doped with, for example, magnesium (Mg) serving as a p-type impurity, and may have an overall thickness of, for example, 0.52 μm.

Formed on the p-type cladding layer 17 is a p-type contact layer 18. The p-type contact layer 18 may be configured using, for example, gallium nitride (GaN). The p-type contact layer 18 may have a thickness of, for example, 100 nm, and may be doped with, for example, Mg serving as a p-type impurity.

It is to be noted that an upper layer part of the p-type cladding layer 17 and the p-type contact layer 18 have a predetermined ridge stripe shape narrowing towards an upper part of FIG. 1. The semiconductor laser 10 may have a cavity length of, for example, 0.8 mm, and a ridge stripe section 21 may have a width of, for example, 2.0 μm.

Further, the ridge stripe section 21 is formed inside a buried layer 22.

Furthermore, as described above, the n-side electrode 11 such as a Ti/Al/Pt/Au electrode, for example, may be provided in contact with the substrate 12, and the p-side electrode 20 such as a Ni/Pt/Au electrode or a Ni/Au electrode, for example may be provided in contact with the p-type contact layer 18.

When the semiconductor laser 10 emits light, a hole carrier flows from top to bottom in FIG. 1, and an electron carrier flows from bottom to top in FIG. 1. Then, the hole carrier and the electron carrier recombine in the active layer 15 to cause light emission. In this case, the light exits in a direction perpendicular to a sheet surface of FIG. 1.

FIG. 2 is a schematic diagram illustrating a band gap of each of the n-type light-guide layer 14 to the p-type cladding layer 17 of FIG. 1. In FIG. 2, a vertical axis represents energy, and a horizontal axis represents positions in a cross section of the semiconductor laser 10. FIG. 2 illustrates a change in energy at a conduction-band lower end of each of the n-type light-guide layer 14 to the p-type cladding layer 17. In the case of FIG. 2, an electron carrier flows from right to left, and a hole carrier flows from left to right in FIG. 2.

As illustrated in FIG. 2, in the active layer 15, an energy position changes discontinuously, and two concave sections are formed in this example. As described above, the active layer 15 includes the quantum well layer made of the n-type GaInN layer and the barrier layer made of the n-type GaInN layer. Each of the two concave sections in FIG. 2 is the quantum well layer of the active layer 15, and a remaining part is the barrier layer of the active layer 15.

Further, as illustrated in FIG. 2, an energy position of the p-type electron barrier layer 16 is higher than those of the n-type light-guide layer 14, the active layer 15, and the p-type cladding layer 17. In other words, a wall (a p-type electron barrier) is allowed to be formed between the active layer 15 and the p-type cladding layer 17 by providing the p-type electron barrier layer 16. Therefore, an electron carrier injected from right in FIG. 2 is prevented from flowing to the p-type cladding layer 17 by passing through the active layer 15.

When the semiconductor laser 10 is caused to emit light, it is necessary to trap an electron carrier in the quantum well layer of the active layer 15, to cause recombination of the electron carrier with the hole carrier. However, the electron carrier passes through the active layer 15 and flows to the p-type cladding layer 17 in some cases. Such a phenomenon is called “electron overflow”. When the electron overflow occurs, the recombination of the electron carrier and the hole carrier which occurs in the active layer 15 decreases. Therefore, injection of more electron carriers is necessary to cause light emission of the semiconductor laser 10. For this reason, when the electron overflow occurs, it is necessary to further increase a current value used to drive the semiconductor laser 10.

By providing the p-type electron barrier layer 16, it is possible to ensure that movement of the electron carrier in a rightward direction in FIG. 2 is stopped at the p-type electron barrier layer 16. This suppresses the occurrence of the electron overflow, and therefore it is not necessary to increase the current value used to drive the semiconductor laser 10, thereby allowing the semiconductor laser 10 to emit light efficiently.

It is to be noted that, in the p-type electron barrier layer 16, the effect of suppressing the electron overflow becomes higher, as a difference from the energy position of the active layer 15 becomes larger, and as the p-type electron barrier layer 16 protrudes upwards further in FIG. 2 (as the p-type electron barrier becomes higher).

In addition, in the present embodiment of the technology, the p-type electron barrier layer 16 includes a first region 16a and a second region 16b as illustrated in FIG. 2. The first region 16a and the second region 16b are configured using materials having different Al elemental composition ratios.

For example, the Al elemental composition ratio of the first region 16a located on a side close to the active layer 15 may be 20%, and a width thereof may be 5 nm. Further, for example, the Al elemental composition ratio of the second region 16b located on a side away from the active layer 15 may be 10%, and a width thereof may be 5 nm.

By thus configuring the first region 16a and the second region 16b using the materials having different Al elemental composition ratios, it is possible to make the band gap of the first region 16a and the band gap of the second region 16b different from each other. In the example of FIG. 2, the band gap of the first region 16a is larger than the band gap of the second region 16b, and the energy position of the first region 16a is higher than the energy position of the second region 16b. Therefore, in the present embodiment of the technology, the p-type electron barrier layer 16 has a band discontinuity point 16c.

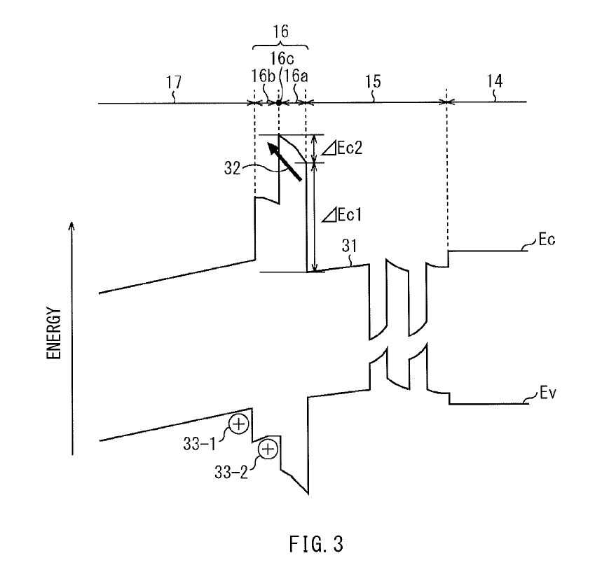

FIG. 3 is a diagram used to describe the band gap of each of the n-type light-guide layer 14 to the p-type cladding layer 17 in FIG. 1 in more detail. In FIG. 3, a vertical axis represents energy, and a horizontal axis represents positions in a cross section of the semiconductor laser 10.

In FIG. 3, a line Ec indicates a change in energy at the conduction-band lower end of each of the n-type light-guide layer 14 to the p-type cladding layer 17, and a line Ev indicates a change in energy at a valence-band upper end of each of the n-type light-guide layer 14 to the p-type cladding layer 17. In the case of FIG. 3, an electron carrier flows from right to left, and a hole carrier flows from left to right, in FIG. 3.

As illustrated in FIG. 3, the p-type electron barrier layer 16 is a layer that increases the band gap, and therefore the energy position at the valence-band upper end is lower than those of the p-type cladding layer 17 and the active layer 15. In addition, as described above, the band gaps of the first region 16a and the second region 16b of the p-type electron barrier layer 16 are different from each other, and therefore the position of the valence-band upper end also changes accordingly. For this reason, in the present embodiment of the technology, the p-type electron barrier layer 16 also has a band discontinuity point on the valence-band side.

Moreover, due to the presence of the p-type electron barrier layer 16, an interface between the p-type cladding layer 17 and the p-type electron barrier layer 16, as well as the discontinuity point of the p-type electron barrier layer 16, each serve as a barrier to the hole carrier moving from left to right in FIG. 3, in the valence band. In the example of FIG. 3, a hole carrier 33-1 and a hole carrier 33-2 which are charged positively in the valence band are illustrated, and these hole carriers are localized at the interface between the p-type cladding layer 17 and the p-type electron barrier layer 16, as well as the discontinuity point of the p-type electron barrier layer 16.

In FIG. 3, ΔEc1 indicates the amount of conduction-band band discontinuity at an interface between the p-type electron barrier layer 16 and a barrier layer 31 in the active layer 15. The barrier layer 31 is a layer closest to the p-type electron barrier layer 16. Further, ΔEc2 indicates a difference between a conduction-band energy peak position in the p-type electron barrier layer 16 and an energy position determined by ΔEc1.

In other words, ΔEc1 is determined uniquely by elemental composition ratios of the compound semiconductors of the p-type electron barrier layer 16 and the barrier layer 31 of the active layer 15. On the other hand, ΔEc2 is determined by a density of hole carriers localized at the p-type electron barrier layer 16 and therearound (a localized hole-carrier density) in the valence band. When the localized hole-carrier density is high, an effect of reducing neighboring band energy is produced, and ΔEc2 is reduced.

For example, when the band gap of the p-type electron barrier layer 16 stays constant, the hole carriers may be substantially localized only at the interface between the p-type cladding layer 17 and the p-type electron barrier layer 16. For this reason, when the p-type electron barrier layer 16 does not have a band discontinuity point, ΔEc2 is decreased, and therefore the p-type electron barrier of the conduction band is lowered, and the effect of suppressing the electron overflow is also reduced.

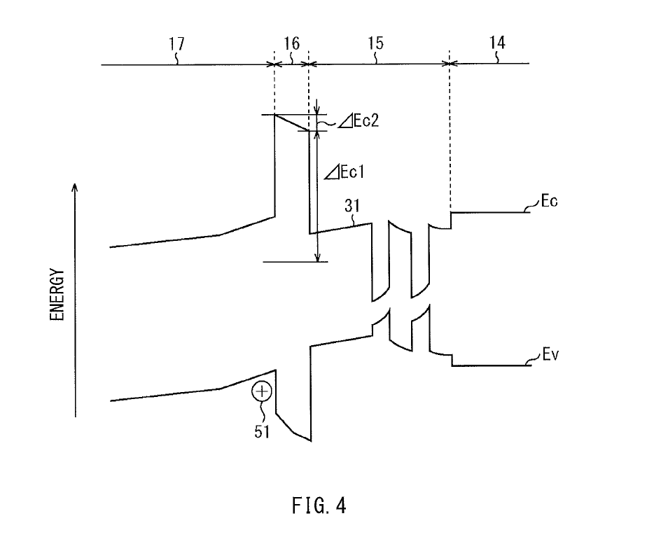

For example, as illustrated in FIG. 4, when the band gap of the p-type electron barrier layer 16 stays constant (when a plurality of regions having different band gaps are not present), a hole carrier 51 is localized at the interface between the p-type cladding layer 17 and the p-type electron barrier layer 16, and a hole carrier localized at the band discontinuity point of the p-type electron barrier layer 16 like the hole carrier 33-2 illustrated in FIG. 3 is not present. For this reason, in the valence band, the localized hole-carrier density of the p-type electron barrier layer 16 and therearound increases. Therefore, ΔEc2 is smaller than that in the case of FIG. 3.

In contrast, according to the present embodiment of the technology, the p-type electron barrier layer 16 has the plurality of regions having different band gaps. Therefore, for example, as illustrated in FIG. 3, the hole carrier is localized at each of the interface between the p-type cladding layer 17 and the p-type electron barrier layer 16, and the discontinuity point of the p-type electron barrier layer 16. This spreads the position where the hole carrier is localized, thereby reducing the localized hole-carrier density of the p-type electron barrier layer 16 and therearound in the valence band.

In this way, according to the present embodiment of the technology, it is possible to reduce the localized hole-carrier density of the p-type electron barrier layer 16 and therearound in the valence band, thereby making the p-type electron barrier layer 16 in the conduction band higher. Therefore, according to the present embodiment of the technology, it is possible to enhance the effect of suppressing the electron overflow, allowing the semiconductor laser 10 to emit light more efficiently.

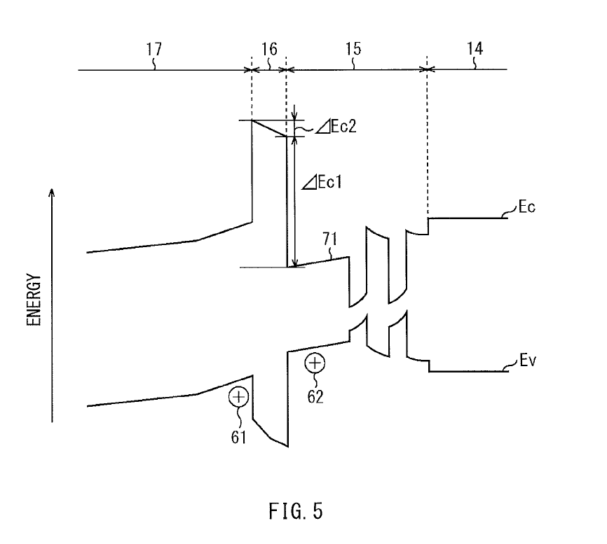

In this regard, it is conceivable to increase ΔEc1, in order to enhance the effect of suppressing the electron overflow. For example, as illustrated in FIG. 5, it is possible to increase the amount of conduction-band band discontinuity at an interface between the p-type electron barrier layer 16 and a barrier layer 71 closest to the p-type electron barrier layer 16 in the active layer 15, by configuring the barrier layer 71 to have a band gap smaller than those of other barrier layers. This appears to make the p-type electron barrier become higher, to allow enhancement of the effect of suppressing the electron overflow.

However, in the case of FIG. 5, the p-type electron barrier layer 16 does not have the plurality of regions having different band gaps. Therefore, a hole carrier 61 is localized at the interface between the p-type cladding layer 17 and the p-type electron barrier layer 16, and a hole carrier localized at the band discontinuity point of the p-type electron barrier layer 16 like the hole carrier 33-2 illustrated in FIG. 3 is not present. For this reason, again, the localized hole-carrier density of the p-type electron barrier layer 16 and therearound in the valence band is increased, and ΔEc2 becomes smaller than that in the case of FIG. 3. Therefore, an improvement in the effect of suppressing the electron overflow is not much expected.

Further, in the case of FIG. 5, the barrier layer 71 closest to the p-type electron barrier layer 16 is configured to have the band gap smaller than those of other barrier layers, and therefore the barrier layer 71 functions as if the barrier layer 71 is a quantum well layer, and attracts the hole carrier. For this reason, a hole carrier 62 is localized also near an interface between the p-type electron barrier layer 16 and the active layer 15 in the valence band, thereby increasing the localized hole-carrier density of this part. Therefore, a lateral hole current is easily generated.

Here, the lateral hole current is a hole current having a horizontal direction component, with respect to a film lamination direction of the semiconductor laser 10. For example, in the semiconductor laser 10, it may be necessary to cause the recombination of the hole carrier and the electron carrier at a predetermined position which is within the active layer 15 and in which a light gain of the quantum well layer is generated. However, when the lateral hole current is generated, the electron carrier and the hole carrier easily recombine at a position where a light gain is not obtained even within the quantum well layer, thereby increasing a threshold current value necessary for oscillation of the semiconductor laser 10.

In contrast, according to the present embodiment of the technology, it is possible to enhance the effect of suppressing the electron overflow, without bringing about easy generation of a lateral hole current.

Further, a piezoelectric field is generated at the band discontinuity point 16c in the p-type electron barrier layer 16, by use of a nitride semiconductor as the material of the semiconductor laser 10. In FIG. 3, the piezoelectric field is indicated by an arrow 32.

The direction of the piezoelectric field is determined by a size relation between two layers forming an interface and a lattice constant of a substrate material. When the band gap in the p-type electron barrier layer 16 is made to become smaller monotonously from the side close to the active layer 15, the lattice constant in the p-type electron barrier layer 16 becomes larger monotonously from the side close to the active layer 15. In this case, at the band discontinuity point 16c in the p-type electron barrier layer 16, the piezoelectric field is typically generated in a direction (for example, a direction indicated by the arrow 32) of raising a conduction-band band energy position of the p-type electron barrier layer 16. This result in an increase in ΔEc2, making it possible to enhance the effect of suppressing the electron overflow.

In other words, in the present embodiment of the technology, the p-type electron barrier layer 16 may be configured using, for example, a nitrogen compound such as aluminum gallium nitride (AlGaN), and therefore the piezoelectric field is generated at the band discontinuity point 16c in the p-type electron barrier layer 16. Hence, it is possible to enhance the effect of suppressing the electron overflow further.

To obtain the above-described effect according to the present embodiment of the technology, it is necessary to select a film thickness sufficient to prevent tunneling of an electron, for the p-type electron barrier layer 16. However, a too-large film thickness causes a rise in voltage, thereby causing deterioration in the characteristics of the semiconductor laser. Therefore, preferably, the film thickness of the first region 16a of the p-type electron barrier layer 16 may be 50 angstroms to 500 angstroms.

In addition, for the p-type electron barrier layer 16, it is necessary to select an Al elemental composition ratio that allows the p-type electron barrier to have a height sufficient to suppress the occurrence of the electron overflow. However, a too-large Al elemental composition ratio increases the current value necessary to drive the semiconductor laser, thereby causing deterioration in the characteristics of the semiconductor laser. Therefore, it is desirable to set an upper limit of the Al elemental composition ratio in the p-type electron barrier layer 16, and preferably, the Al elemental composition ratio of the first region 16a of the p-type electron barrier layer 16 may be 5% to 20%.

Moreover, it is necessary to select the difference between the Al elemental composition ratio of the first region 16a formed in the p-type electron barrier layer 16 and the Al elemental composition ratio of the second region 16b formed in the p-type electron barrier layer 16, so as to allow a sufficient reduction in the hole carrier density at the interface in the p-type electron barrier layer 16. Besides, it is necessary to generate a piezoelectric field sufficient to raise the conduction-band band energy position of the p-type electron barrier layer 16, at the band discontinuity point 16c. Therefore, preferably, the difference between the Al elemental composition ratio of the first region 16a formed in the p-type electron barrier layer 16 and the Al elemental composition ratio of the second region 16b formed in the p-type electron barrier layer 16 may be 1% to 15%.

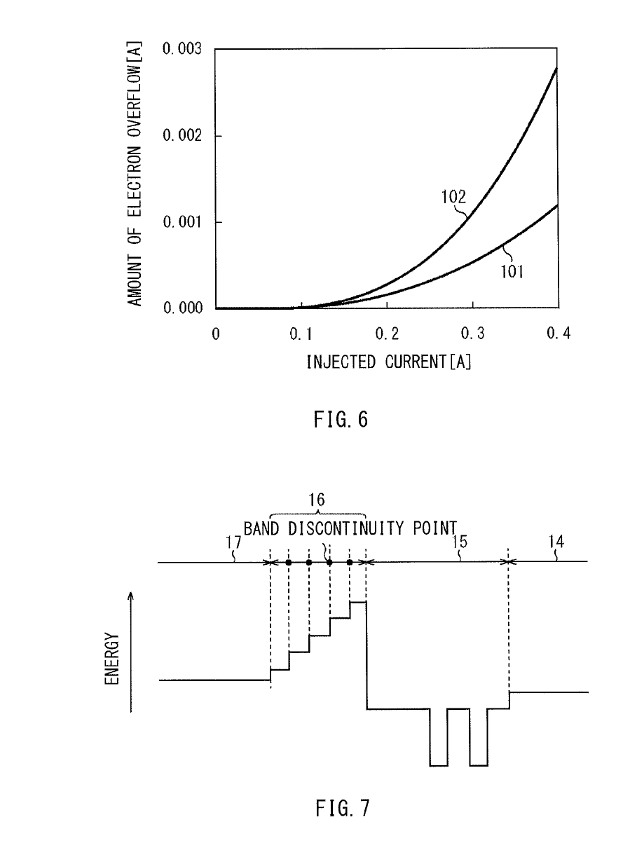

FIG. 6 is a diagram used to describe simulation results according to semiconductor lasers. In FIG. 6, a vertical axis represents the amount of electron overflow, and a horizontal axis represents injected current values. A simulation result of the semiconductor laser 10 to which an embodiment of the present technology is applied is indicated by a line 101, and a simulation result of a typical semiconductor laser is indicated by a line 102.

In each simulation model, an In elemental composition ratio of a quantum well layer made of GaInN was 8%, and a thickness thereof was 5 nm. Further, the quantum well layer was sandwiched between barrier layers made of GaInN, and had an In elemental composition ratio of 4%. It is to be noted that the number of quantum well layers included in an active layer was three, and an emission wavelength of the semiconductor laser was about 400 nm.

In the simulation model (the semiconductor laser 10 to which an embodiment of the present technology is applied) according to the line 101, the p-type electron barrier layer 16 had the band discontinuity point 16c at one position. The Al elemental composition ratio of the first region 16a close to the active layer 15 was 20%, and the width thereof was 5 nm. The Al elemental composition ratio of the second region 16b away from the active layer 15 was 10%, and the width thereof was 10 nm.

On the other hand, in the simulation model (the typical semiconductor laser) according to the line 102, a p-type electron barrier layer 16 was configured not to have a band discontinuity point, an Al elemental composition ratio was constant (20%), and a width was 10 nm. Structures other than the p-type electron barrier layer 16 were configured in a manner similar to that of the simulation model according to the line 101.

As illustrated in FIG. 6, when the injected current value increases, the amount of electron overflow also increases. However, in the line 101, the increase in the electron overflow accompanying the increase in the injected current value is suppressed, as compared with the line 102. In other words, it is found that the semiconductor laser 10 to which an embodiment of the present technology is applied is able to reduce the amount of electron overflow, as compared with the typical semiconductor laser.

In the example illustrated in FIG. 3, the p-type electron barrier layer 16 has been described as having the one band discontinuity point 16c. However, the p-type electron barrier layer 16 may have two or more discontinuity points.

FIG. 7 is a diagram used to describe a configuration example according to another embodiment of the present technology. FIG. 7 is a schematic diagram illustrating another example of the band gap of each of the n-type light-guide layer 14 to the p-type cladding layer 17 in FIG. 1. In FIG. 7, a vertical axis represents energy, a horizontal axis represents positions in a cross section of the semiconductor laser 10, and a change in the energy at the conduction-band lower end of each of the n-type light-guide layer 14 to the p-type cladding layer 17 is illustrated. In the case of FIG. 7, an electron carrier flows from right to left, and a hole carrier flows from left to right, in FIG. 7.

In the case of the example of FIG. 7, the p-type electron barrier layer 16 has a plurality of (four, in this example) band discontinuity points, unlike the case of FIG. 2. In other words, in the case of FIG. 7, the p-type electron barrier layer 16 is formed such that the band gap becomes largest in a region close to the active layer 15, and the band gap gradually decreases towards the p-type cladding layer 17. In other words, in the case of FIG. 7, the p-type electron barrier layer 16 is configured to have five regions where the band gaps are smaller monotonously from right to left in FIG. 7.

It is to be noted that, in FIG. 7, the band discontinuity points of the p-type electron barrier layer 16 are illustrated as four, but the number of band discontinuity points may be one or more.

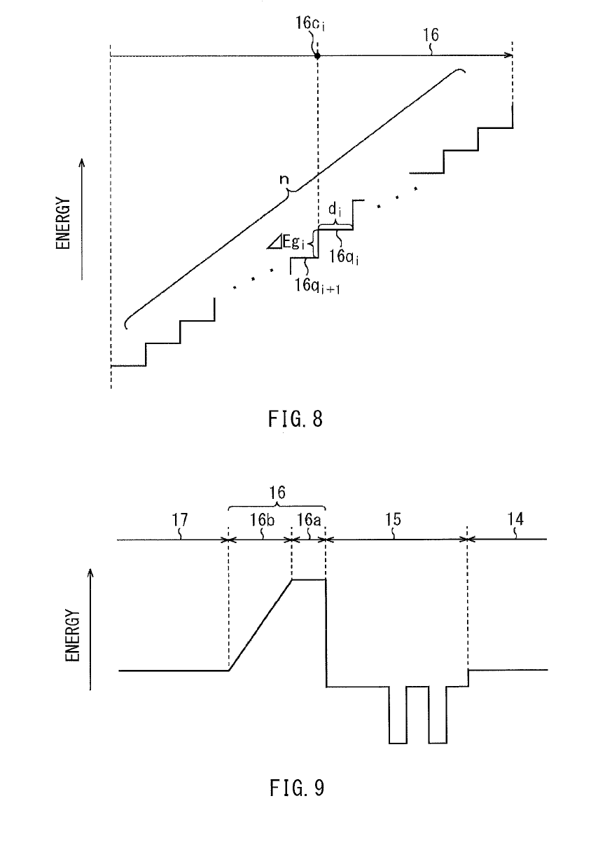

FIG. 8 is a schematic diagram illustrating the example of the band gap of the p-type electron barrier layer 16 in FIG. 7 in detail. In this example, the p-type electron barrier layer 16 is assumed to have band discontinuity points 16c, the number of which is “m”, and also to have regions 16q₁, 16q₂, . . . , and 16qₙ the number of which is “n” and which have different Al elemental composition ratios. Here, “n” is assumed to be an integer satisfying n≧3.

In the p-type electron barrier layer 16, the region 16qᵢ located at the ith position (n≧i≧1) counted from the one closest to the active layer 15 may have the Al elemental composition ratio of, for example, 10%, and a width of, for example, 10 nm. In this case, the Al elemental composition ratio of the region 16qᵢ₊₁ is typically smaller than the Al elemental composition ratio of the region 16qᵢ, which may be, for example, 8%. The width thereof may be, for example, 10 nm.

It is to be noted that, in the p-type electron barrier layer 16, when a configuration in which a band discontinuity point is provided, the difference between the Al elemental composition ratios of adjacent two semiconductor layers sandwiching the band discontinuity point may be, preferably, for example, 2% or more, at one or more positions. In addition, for example, preferably, the difference in terms of Al elemental composition ratio may be 18% or less at any position.

Moreover, as illustrated in FIG. 8, when the width of the region 16qᵢ is represented by dᵢ, dᵢ and dᵢ₊₁ may not be necessarily the same, and the widths may vary among the regions. Further, when the difference between the band gap of the region 16qᵢ and the band gap of the region 16qᵢ₊₁ is represented by ΔEgᵢ, ΔEgᵢ and ΔEgᵢ₊₁ may not be necessarily the same, and the differences may vary among the discontinuity points.

It is to be noted that, in the p-type electron barrier layer 16, when a configuration in which a band discontinuity point is provided, the amount of band discontinuity of one on the conduction band side of adjacent two semiconductor layers sandwiching the band discontinuity point, may be, preferably, for example, 50 meV or more at one or more positions. Further, the amount of band discontinuity of one on the valence band side may be, preferably, for example, 100 meV or less at any position.

The configuration of having one or more band discontinuity points in the p-type electron barrier layer 16 has been described above. By providing one or more band discontinuity points in the p-type electron barrier layer 16, as described above, the position where the hole carrier is localized is spread, and the localized hole-carrier density of the p-type electron barrier layer 16 and therearound in the valence band is reduced.

However, a hole carrier may be localized at the band discontinuity point in the p-type electron barrier layer 16. For example, in the example of FIG. 3, the hole carrier 33-2 may be localized at the band discontinuity point in the p-type electron barrier layer 16. Therefore, the localized hole-carrier density may be high at the band discontinuity point in the p-type electron barrier layer 16, which may pose a limitation to an effect of suppressing the generation of the lateral hole current.

Therefore, for example, a configuration in which no band discontinuity point is present in the p-type electron barrier layer 16 may be adopted.

FIG. 9 is a diagram used to describe a configuration example according to still another embodiment of the present technology. FIG. 9 is a schematic diagram illustrating still another example of the band gap of each of the n-type light-guide layer 14 to the p-type cladding layer 17 in FIG. 1. In FIG. 9, a vertical axis represents energy, a horizontal axis represents positions in a cross section of the semiconductor laser 10, and a change in the energy at the conduction-band lower end of each of the n-type light-guide layer 14 to the p-type cladding layer 17 is illustrated. In the case of FIG. 9, an electron carrier flows from right to left, and a hole carrier flows from left to right, in FIG. 9.

In the case of the example illustrated in FIG. 9, no band discontinuity point is formed between the first region 16a and the second region 16b of the p-type electron barrier layer 16, unlike the case of FIG. 2. In other words, the band gap from the active layer 15 to the p-type cladding layer 17 is configured to become linearly smaller from right to left in FIG. 9. That is, in the example illustrated in FIG. 9, the band gap of the second region 16b has the same magnitude as that of the band gap of the first region 16a at an interface with the first region 16a, and continuously changes to become smaller from right to left in FIG. 9. In this case, the p-type electron barrier layer 16 has a flat portion formed by an energy position of the first region 16a, and a slope portion formed by an energy position of the second region 16b.

In the case of the example illustrated in FIG. 9, for example, the Al elemental composition ratio of the first region 16a may be 20%, and the Al elemental composition ratio of the second region 16b may be linearly modulated from 20% to 1%.

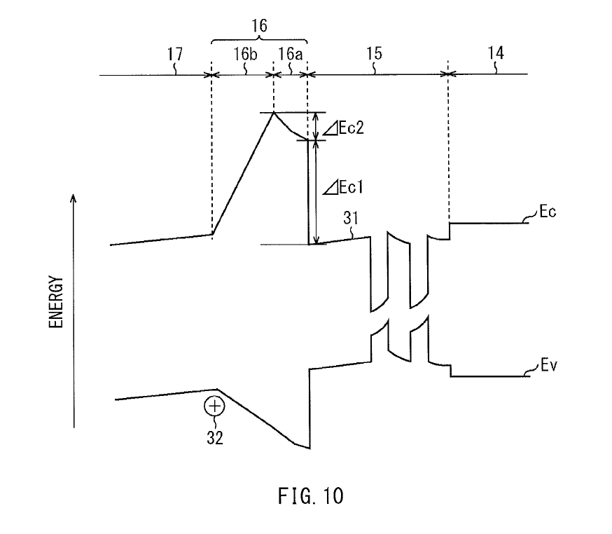

FIG. 10 is a diagram used to describe the band gap of FIG. 9 in more detail. In FIG. 10, a vertical axis represents energy, and a horizontal axis represents positions in a cross section of the semiconductor laser 10.

In FIG. 10, a line Ec indicates a change in the energy at the conduction-band lower end of each of the n-type light-guide layer 14 to the p-type cladding layer 17, and a line Ev indicates a change in the energy at the valence-band upper end of each of the n-type light-guide layer 14 to the p-type cladding layer 17. In the case of FIG. 10, an electron carrier flows from right to left, and a hole carrier flows from left to right, in FIG. 9.

As illustrated in FIG. 10, the p-type electron barrier layer 16 is provided to increase the band gap, and therefore the energy position at the valence-band upper end is lower than those of the p-type cladding layer 17 and the active layer 15. However, in the case of FIG. 10, unlike the case of FIG. 3, the p-type electron barrier layer 16 does not have a band discontinuity point on the valence band side either, and the band gap is formed to become smaller linearly from right to left in FIG. 10.

In the valence band, part of hole carriers moving from left to right in FIG. 10 is stopped at the interface between the p-type cladding layer 17 and the p-type electron barrier layer 16, due to the presence of the p-type electron barrier layer 16. However, in the case of FIG. 10, unlike the case of FIG. 3, most hole carriers flow to the active layer 15 by crossing the p-type electron barrier, due to the absence of a discontinuity point of the p-type electron barrier layer 16. For this reason, although the hole carrier is localized at the interface between the p-type cladding layer 17 and the p-type electron barrier layer 16, the localized hole-carrier density is not so high.

In this way, in the case of the example illustrated in FIG. 10, it is possible to further enhance the effect of suppressing the generation of the lateral hole current, as compared with the case of FIG. 3, for example.

Further, ΔEc1 indicates the amount of conduction-band band discontinuity at an interface between the p-type electron barrier layer 16 and the barrier layer 31 closest to the p-type electron barrier layer 16 in the active layer 15. Furthermore, ΔEc2 indicates the difference between the conduction-band energy peak position in the p-type electron barrier layer 16 and the energy position determined by ΔEc1.

In other words, ΔEc1 is determined uniquely by elemental composition ratios of the compound semiconductors of the p-type electron barrier layer 16 and the barrier layer 31 of the active layer 15. On the other hand, ΔEc2 is determined by the density of hole carriers localized at the p-type electron barrier layer 16 and therearound (the localized hole-carrier density) in the valence band. When the localized hole-carrier density is high, an effect of reducing neighboring band energy is produced, which decreases ΔEc2.

In the case of the example illustrated in FIG. 10, the localized hole-carrier density at the interface between the p-type cladding layer 17 and the p-type electron barrier layer 16 is not high, and therefore ΔEc2 is not decreased. Therefore, like the case of FIG. 3, it is possible to enhance the effect of suppressing the electron overflow.

However, when the p-type electron barrier layer 16 is configured as illustrated in FIG. 10, it is necessary to linearly modulate the Al elemental composition ratio of the second region 16b from 20% to 1%, and therefore a higher technique may be necessary to manufacture the semiconductor laser 10.

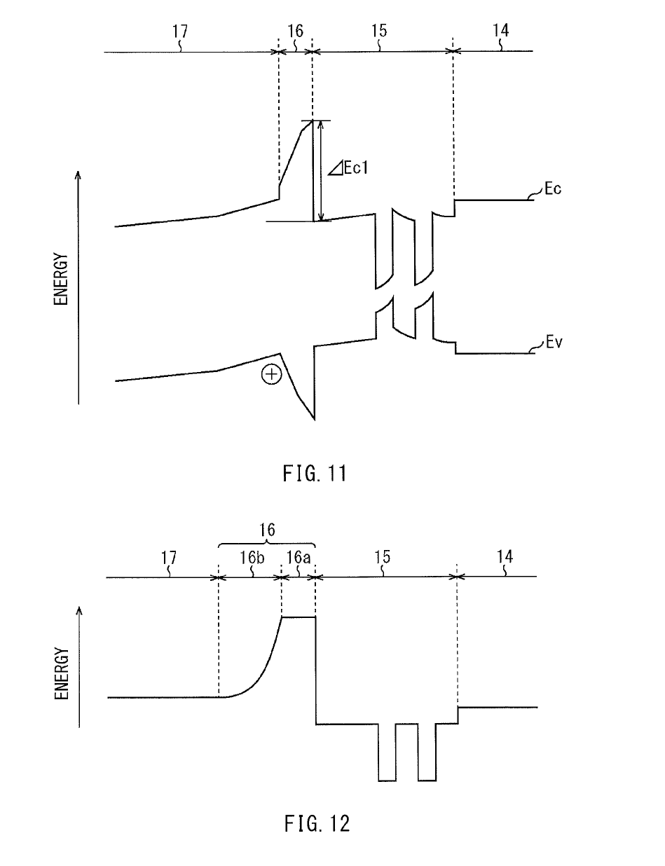

It is to be noted that it seems possible to obtain a similar effect by linearly changing the band gap of the p-type electron barrier layer 16 from a position close to the active layer 15 to a position close to the p-type cladding layer 17. For example, as illustrated in FIG. 11, it is possible to enhance the effect of suppressing the generation of the lateral hole current, if a configuration of changing the band gap of the p-type electron barrier layer 16 is adopted.

However, in the case of the example of FIG. 11, the first region 16a is not provided in the p-type electron barrier layer 16, and therefore the electron barrier height of the conduction band does not exceed ΔEc1. In other words, when the flat portion of the energy position formed by the first region 16a exists in the p-type electron barrier layer 16, ΔEc2 is allowed to be generated. When the flat portion of the energy position formed by the first region 16a does not exist in the p-type electron barrier layer 16 like FIG. 11, the electron barrier height of the conduction band is not so long. As a result, in the case of the example of FIG. 11, it is difficult to enhance the effect of suppressing the electron overflow.

In contrast, in the case of the configuration of FIG. 10 to which an embodiment of the present technology is applied, the flat portion of the energy position formed by the first region 16a exists. Therefore, it is possible to form the electron barrier having a height achieved by the addition of ΔEc2 to ΔEc1, thereby allowing enhancement of the effect of suppressing the electron overflow.

In FIG. 9, the second region 16b is configured such that the band gap becomes smaller linearly from right to left in FIG. 9, but the change of the band gap may not be linear.

FIG. 12 is a diagram used to describe a configuration example according to yet still another embodiment of the present technology. FIG. 12 is a schematic diagram illustrating yet still another example of the band gap of each of the n-type light-guide layer 14 to the p-type cladding layer 17 in FIG. 1. In FIG. 12, a vertical axis represents energy, a horizontal axis represents positions in a cross section of the semiconductor laser 10, and a change in the energy at the conduction-band lower end of each of the n-type light-guide layer 14 to the p-type cladding layer 17 is illustrated. In the case of FIG. 12, an electron carrier flows from right to left, and a hole carrier flows from left to right, in FIG. 12.

In the case of the example illustrated in FIG. 12, unlike the case of FIG. 9, the second region 16b is configured to have the band gap that becomes smaller from right to left in FIG. 9 linearly and curvilinearly. In this case, likewise, again, the p-type electron barrier layer 16 has a flat portion of the energy position formed by the first region 16a and a slope portion formed by the second region 16b.

In the case of the example illustrated in FIG. 12, like the case described above with reference to FIG. 10, again, for example, it is possible to enhance the effect of suppressing the generation of the lateral hole current as compared with the case of FIG. 3. In addition, in the case of the example illustrated in FIG. 12, likewise, the flat portion of the energy position formed by the first region 16a exists, and therefore, for example, again, it is possible to enhance the effect of suppressing the electron overflow as compared with the case of FIG. 11.

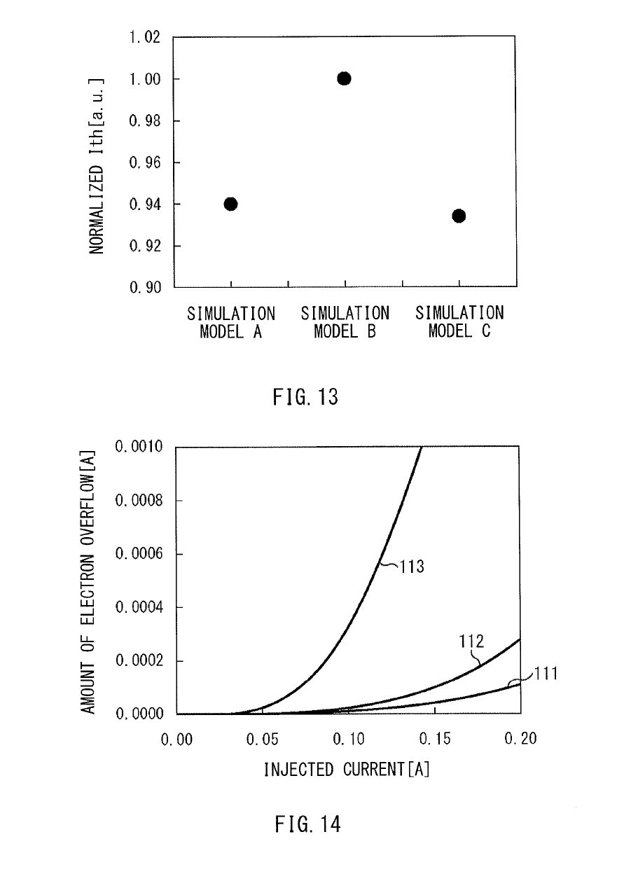

FIG. 13 is a diagram used to describe simulation results according to semiconductor lasers. In FIG. 13, a vertical axis represents current values injected into a semiconductor laser. FIG. 13 illustrates the current value necessary to cause normal light emission of the semiconductor laser, for each simulation model. In this example, the current value (which will be each referred to as “threshold current”), which is necessary to cause normal light emission of the semiconductor laser corresponding to each of a simulation model A, a simulation model B, and a simulation model C, is plotted.

The simulation model A is the semiconductor laser 10 to which an embodiment of the present technology is applied, and may be, for example, the semiconductor laser corresponding to the example illustrated in FIG. 10. For a comparison, simulation was performed using the semiconductor laser corresponding to the example illustrated in FIG. 4 as the simulation model B, and the semiconductor laser corresponding to the example illustrated in FIG. 11 as the simulation model C.

In each of the simulation models, the quantum well layer made of GaInN had an In elemental composition ratio of 8%, and a thickness of 5 nm. In addition, the quantum well layer was sandwiched between barrier layers made of GaInN, and had an In elemental composition ratio of 4%. It is to be noted that, the number of quantum well layers included in the active layer was three, and an emission wavelength of the semiconductor laser as about 400 nm.

In the simulation model A (the semiconductor laser 10 to which an embodiment of the present technology is applied), the p-type electron barrier layer 16 was configured to have the first region 16a and the second region 16b. The first region 16a close to the active layer 15 had an Al elemental composition ratio of 20%, and a width of 10 nm. The second region 16b away from the active layer 15 had an Al elemental composition ratio linearly decreased from 20% to 1%, and a width of 20 nm.

Meanwhile, the simulation model B (the semiconductor laser corresponding to FIG. 4) was configured such that the p-type electron barrier layer 16 did not have a band discontinuity point, and had a constant Al elemental composition ratio (20%) and a width of 10 nm. Except for the structure of the p-type electron barrier layer 16, the simulation model B was configured in a manner similar to that of the simulation model A.

Further, the simulation model C (the semiconductor laser corresponding to FIG. 11) was configured such that the p-type electron barrier layer 16 did not have a region of a constant Al elemental composition ratio. In other words, the p-type electron barrier layer 16 had an Al elemental composition ratio linearly decreased from 20% to 1% from the active layer 15 towards the p-type cladding layer 17, and a width of 10 nm. Except for the structure of the p-type electron barrier layer 16, the simulation model C was configured in a manner similar to that of the simulation model A

As illustrated in FIG. 13, when the threshold current of the simulation model B was 1.00, a relative value of the threshold current decreased to 0.94 in each of the simulation model A and the simulation model C. Therefore, it was found that a reduction in the threshold current was achieved.

FIG. 14 is another diagram used to describe the simulation results according to the semiconductor lasers. In FIG. 14, a vertical axis represents the amount of electron overflow, and a horizontal axis represents injected current values. The simulation result according to the simulation model A (the semiconductor laser 10 to which an embodiment of the present technology is applied) is indicated by a line 111, the simulation result according to the simulation model B (the semiconductor laser corresponding to FIG. 4) is indicated by a line 112, and the simulation result according to the simulation model C (the semiconductor laser corresponding to FIG. 11) is indicated by a line 113.

As illustrated in FIG. 14, when the injected current value increased, the amount of electron overflow also increased. However, in the line 111, the increase in the amount of electron overflow accompanying the increase in the injected current value was suppressed, as compared with the line 112 and the line 113. In other words, it is found that the semiconductor laser 10 to which an embodiment of the present technology is applied is able to reduce the amount of electron overflow, as compared with the semiconductor laser corresponding to FIG. 4 and the semiconductor laser corresponding to FIG. 11.

Next, a method of manufacturing of the semiconductor laser 10 of FIG. 1 will be described.

First, the substrate 12 is prepared. The substrate 12 may be made of, for example, GaN, and a buffer layer may be caused to grow on a surface of the substrate 12 by, for example, a MOCVD (Metal Organic Chemical Vapor Deposition) method. A growth temperature may be, for example, 1,050° C.

Subsequently, the n-type cladding layer 13 made of AlGaN is caused to grow similarly by the MOCVD method, while the growth temperature is kept at, for example, 1,050° C.

Afterwards, the n-type light-guide layer 14, the active layer 15, the p-type electron barrier layer 16, the p-type cladding layer 17, and the p-type contact layer 18 are caused to grow sequentially by the MOCVD method likewise. In this process, the p-type electron barrier layer 16 is caused to grow such that, as described above, the band gap is constant in the first region 16a, and the band gap is monotonously decreased from the active layer 15 side to the p-type cladding layer 17 side by modulating the composition ratio, in the second region 16b.

It is to be noted that, when MOCVD is performed, trimethylgallium ((CH3)3Ga), for example, may be used as a source gas of gallium, trimethylaluminum ((CH3)3Al), for example, may be used as a source gas of aluminum, and trimethylindium ((CH3)3In), for example, may be used as source gas of indium. In addition, ammonia (NH3), for example, may be used as a source gas of nitrogen. Moreover, monosilane (SiH4), for example, may be used as a source gas of silicon, and bis(cyclopentadienyl)magnesium ((C5H5)5Mg), for example, may be used as a source gas of magnesium.

Further, a not-illustrated mask is formed on the p-type contact layer 18. Using this mask, a part of each of the p-type contact layer 18 and the p-type cladding layer 17 may be selectively removed by, for example, RIE (Reactive Ion Etching). Thus, an upper part of the p-type cladding layer 17 and the p-type contact layer 18 are processed into a ridge stripe section 21 shaped like a thin stripe.

Next, the buried layer 22 made of, for example, SiO2 or SiN may be formed on the p-type cladding layer 17 and the p-type contact layer 18. In the buried layer 22, an opening section corresponding to the top surface of the ridge stripe section 21 is provided, and the p-side electrode 20 is formed.

Further, a back-surface side of the substrate 12 may be, for example, lapped or polished, to provide the substrate 12 with a thickness of, for example, about 100 μm. Subsequently, the n-side electrode 11 is formed on the back surface of the substrate 12.

Afterwards, the substrate 12 is adjusted to have a predetermined size, and a not-illustrated reflecting mirror film is formed on each of a pair of cavity facets facing each other. The semiconductor laser 10 illustrated in FIG. 1 is thereby completed.

In this way, the semiconductor laser 10 may be manufactured.

It is to be noted that a series of processes described above herein includes, not to mention processes performed chronologically in the described order, processes performed in parallel or individually, without being necessarily performed chronologically.

Moreover, embodiments of the present technology are not limited to the embodiments described above, and may be variously modified in the scope with no deviation from the gist of the present technology.

Furthermore, the technology encompasses any possible combination of some or all of the various embodiments described herein and incorporated herein.

It is possible to achieve at least the following configurations from the above-described example embodiments of the disclosure.
(1) A semiconductor light-emission device including:

a p-type conductive layer that is one or more layers each made of a III-V compound semiconductor;

an active layer made of a III-V compound semiconductor; and an electron barrier layer inserted between the p-type conductive layer and the active layer, and made of a III-V compound semiconductor, the electron barrier layer including a first region and a second region,

the first region being provided closer to the active layer than the second region in the electron barrier layer, having a first interface and a second interface that is located farther from the active layer than the first interface, and having a band gap of a fixed magnitude, and

the second region being provided in contact with the second interface of the first region, and having a band gap of a magnitude that is smaller than the magnitude of the band gap of the first region and becomes smaller from an interface with the first region of the second region towards an interface with the p-type conductive layer of the second region.
(2) The semiconductor light-emission device according to (1), further including a band discontinuity point at which the magnitudes of the band gaps at the interface between the first region and the second region become discontinuous.
(3) The semiconductor light-emission device according to (2), wherein

the second region is divided into a plurality of regions that have different band gaps from one another, and

the plurality of regions are disposed to have the band gaps smaller from the interface with the first region towards the interface with the p-type conductive layer.
(4) The semiconductor light-emission device according to (1), wherein, in the second region,

the magnitude of the band gap at the interface with the first region is equal to the magnitude of the band gap of the first region, and

the magnitude of the band gap changes continuously from the interface between the first region and the second region to the interface with the p-type conductive layer.
(5) The semiconductor light-emission device according to any one of (1) to (4), wherein the III-V compound semiconductor forming the electron barrier layer is a III-V compound semiconductor including nitrogen.
(6) The semiconductor light-emission device according to any one of (1) to (5), wherein

the III-V compound semiconductor forming the electron barrier layer is a III-V compound semiconductor including nitrogen, aluminum, and gallium, and

an elemental composition ratio of the aluminum of the first region is about 5% to about 20%.
(7) The semiconductor light-emission device according to any one of (1) to (6), wherein the first region of the electron barrier layer has a film thickness that is about 50 angstroms to about 500 angstroms.
(8) A method of manufacturing a semiconductor light-emission device, the method including:

providing, in an electron barrier layer of the semiconductor light-emission device, a first region having a band gap of a fixed magnitude, the electron barrier layer being made of a III-V compound semiconductor and being inserted between a p-type conductive layer and an active layer of the semiconductor light-emission device, the p-type conductive layer being one or more layers each made of a III-V compound semiconductor, and the active layer being made of a III-V compound semiconductor; and
providing, in the electron barrier layer, a second region that is provided in contact with a second interface of the first region, the first region being provided closer to the active layer than the second region in the electron barrier layer and having a first interface and the second interface that is located farther from the active layer than the first interface, and the second region having a band gap of a magnitude that is smaller than the magnitude of the band gap of the first region and becomes smaller from an interface with the first region of the second region towards an interface with the p-type conductive layer of the second region.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor light-emission device comprising:
a p-type conductive layer that is one or more layers each made of a III-V compound semiconductor;
an active layer made of a III-V compound semiconductor; and
an electron barrier layer inserted between the p-type conductive layer and the active layer, and made of a III-V compound semiconductor, the electron barrier layer including a first region and a second region,
the first region being provided closer to the active layer than the second region in the electron barrier layer, having a first interface and a second interface that is located farther from the active layer than the first interface, and having a band gap of a fixed magnitude, and
the second region being provided in contact with the second interface of the first region, and having a band gap of a magnitude that is smaller than the magnitude of the band gap of the first region and becomes smaller from an interface with the first region of the second region towards an interface with the p-type conductive layer of the second region.

2. The semiconductor light-emission device according to claim 1, further comprising a band discontinuity point at which the magnitudes of the band gaps at the interface between the first region and the second region become discontinuous.

3. The semiconductor light-emission device according to claim 2, wherein
the second region is divided into a plurality of regions that have different band gaps from one another, and
the plurality of regions are disposed to have the band gaps smaller from the interface with the first region towards the interface with the p-type conductive layer.

4. The semiconductor light-emission device according to claim 1, wherein, in the second region,
the magnitude of the band gap at the interface with the first region is equal to the magnitude of the band gap of the first region, and
the magnitude of the band gap changes continuously from the interface between the first region and the second region to the interface with the p-type conductive layer.

5. The semiconductor light-emission device according to claim 1, wherein the III-V compound semiconductor forming the electron barrier layer is a III-V compound semiconductor including nitrogen.

6. The semiconductor light-emission device according to claim 1, wherein
the III-V compound semiconductor forming the electron barrier layer is a III-V compound semiconductor including nitrogen, aluminum, and gallium, and
an elemental composition ratio of the aluminum of the first region is about 5% to about 20%.

7. The semiconductor light-emission device according to claim 1, wherein the first region of the electron barrier layer has a film thickness that is about 50 angstroms to about 500 angstroms.

8. A method of manufacturing a semiconductor light-emission device, the method comprising:
providing, in an electron barrier layer of the semiconductor light-emission device, a first region having a band gap of a fixed magnitude, the electron barrier layer being made of a III-V compound semiconductor and being inserted between a p-type conductive layer and an active layer of the semiconductor light-emission device, the p-type conductive layer being one or more layers each made of a III-V compound semiconductor, and the active layer being made of a III-V compound semiconductor; and
providing, in the electron barrier layer, a second region that is provided in contact with a second interface of the first region, the first region being provided closer to the active layer than the second region in the electron barrier layer and having a first interface and the second interface that is located farther from the active layer than the first interface, and the second region having a band gap of a magnitude that is smaller than the magnitude of the band gap of the first region and becomes smaller from an interface with the first region of the second region towards an interface with the p-type conductive layer of the second region.
